(19) United States
(12) Patent Application Publication
(10) Pub. No.: US 2004/0188702 A1
(43) Pub. Date: Sep. 30, 2004

(54) Semiconductor laser diode

(75) Inventors: Georg Bruderl, Burglengenfeld (DE); Uwe Strauss, Bad Abbach (DE); Alfred Lell, Maxhutte-Haidhof (DE)

Correspondence Address: COHEN, PONTANI, LIEBERMAN & PAVANE, Suite 1210, 551 Fifth Avenue, New York, NY, 10176, US

(73) Assignee: Osram Opto Semiconductors GmbH, Regensburg (DE)

(21) Appl. No.: 10/746,954

(22) Filed: Dec. 23, 2003

(30) Foreign Application Priority Data
Dec. 30, 2002 (DE) 102 61 425.3

(51) Int. Cl. H01L 33/00

(52) U.S. Cl. 257/103; 257/98

(57) ABSTRACT

A semiconductor laser diode having a semiconductor body (12) with a photon-emitting active layer (16) based on a nitride compound semiconductor. A resonator contact (24) is arranged on the semiconductor body (12), and a connection contact area (22) is electrically connected to the resonator contact (24). An uncovered free region (26) is provided at the surface of the semiconductor body (12) in a manner adjoining the resonator contact (24), at which free region hydrogen (30) can escape from the semiconductor body (12).

### CROSS REFERENCE TO RELATED APPLICATIONS

This patent application claims the priority of German patent application 10261425.3-33, the disclosure content of which is hereby incorporated by reference.

### FIELD OF THE INVENTION

The invention relates to a semiconductor laser diode having a semiconductor body with a photon-emitting active layer based on a nitride compound semiconductor, a resonator contact (in particular a resonator metallization) arranged on the semiconductor body, and a connection contact area electrically connected to the resonator contact.

### BACKGROUND OF THE INVENTION

Light-emitting or laser diodes based on a nitride compound semiconductor, for instance based on AlₓIn_{y}Ga_{1-x-y}N, where 0≦x≦1, 0≦y≦1 and x+y≦1, have a shortcoming in that the p-type conductivity of a p-doped AlₓIn_{y}Ga_{1-x-y}N layer can be reduced or even completely prevented by the incorporation of hydrogen.

Attempts have been made to avoid the problem by driving out the hydrogen as completely as possible during the production process by means of suitable measures. However, this approach has generally not been completely successful. Furthermore, during certain steps of the production process, such as in applying a passivation layer, hydrogen can again be undesirably introduced into the p-type layers.

During operation of the finished semiconductor component, hydrogen contained in the p-type layers may then diffuse to the interface of p-type semiconductor/p-type metal and p-type semiconductor/passivation layer, for example, due to the influence of temperature. The increased presence of hydrogen at the p-type metal brings about an increase in the p-type contact resistance and thus also an undesirable increase in the forward voltage.

A conventional way for avoiding this shortcoming is to activate the p-type layers as much as possible prior to processing. Also, the number of critical processing steps is reduced as much as possible. However, this is usually associated with a considerable intervention in the processing sequence and thus with increased manufacturing costs.

For light-emitting diodes, the co-pending U.S. patent application Ser. No. 10/296,195 proposed the use of patterned metallizations. More specifically, a multiplicity of openings are made in a contact layer applied on the p-doped semiconductor layer, which openings primarily improve the coupling-out of light from the contact layer. Moreover, hydrogen from the p-type layer can also escape via these openings.

The openings are embodied in circular form, hexagonal form or in the form of elongated slots and have cross-sectional dimensions which are less than twice the lateral current extension in the p-doped layer, which amounts to a few tenths of a μm to a few μm. On the other hand, the cross-sectional dimensions have a value of more than a quarter of the wavelength of the light generated, that is to say more than about 50 nm.

This solution cannot be applied in a simple manner to the processing of laser diodes because a perforated contact reduces the contact area which, for instance in the case of AlInGaN laser diodes having relatively large p-type contact resistances and only small contact areas anyway, would lead to an unacceptable increase in the forward voltages.

### SUMMARY OF THE INVENTION

One object of the present invention is to provide a semiconductor laser diode of the type described above having improved ageing properties and, in particular, having a stable forward voltage.

This and other objects are attained in accordance with one aspect of the invention directed to a semiconductor laser diode having a semiconductor body with a photon-emitting active layer based on a nitride compound semiconductor, a resonator contact arranged on the semiconductor body, and a connection contact area electrically connected to the resonator contact. An uncovered free region is provided at the surface of the semiconductor body in a manner adjoining the resonator contact, at which free region hydrogen can escape from the semiconductor body.

In particular, in the free region, an insulating or high-resistance layer is advantageously provided at the surface of the semiconductor body. A layer of this type effectively prevents fault currents, so that it is possible to dispense with a hydrogen-retaining passivation layer that fulfils this function in the free region. Furthermore, the connection between the connection contact area and the resonator contact can be kept in small-area fashion.

In order to produce an insulating or high-resistance layer at the surface of the semiconductor body, the semiconductor below the connection contact area and also below the electrical connection to the resonator contact, or else only below the electrical connection to the resonator contact, may be treated for example by means of damage etching in such a way as to form an insulating or high-resistance layer which substantially prevents fault currents. The term “damage etching” means that the semiconductor is etched in a way that leads to a damaged semiconductor surface (regarding the crystal surface). Usually such an etch process is detrimental for the semiconductor body and its further processing, but for achievement of electrical isolation a “damage etch step” can be applied with advantage since it results in the intended isolating surface.

In a preferred development of the invention, the resonator contact is embodied in the form of a contact strip and the free region extends on both sides along the contact strip.

The connection contact area is electrically connected to the resonator contact at one or more contact zone(s) (for example connecting bridges). In this arrangement, the connection contact area crosses the free region at the contact zone(s).

In this embodiment, the connection contact area is advantageously insulated from the semiconductor body by a passivation layer in the region adjoining the contact zone(s).

In accordance with another embodiment of the invention, the free region adjoining the resonator contact forms a part of a lateral wave-guiding structure of the laser diode. In many laser structures, such as the so-called ridge waveguide lasers, for instance, the lateral wave-guiding is determined by the difference in the refractive indices of semiconductor and adjoining passivation material. Since, in the free region, the ambient air in this respect undertakes the role of the passivation and air has a lower refractive index than any other customary passivation material, the lateral wave-guiding is improved as compared with conventional configurations.

In a preferred embodiment of the semiconductor laser diode according to the invention, the semiconductor body comprises a layer sequence formed from an n-conducting nitride compound semiconductor, an active layer and a p-conducting nitride compound semiconductor. The resonator contact is arranged on the p-conducting nitride compound semiconductor. The active layer may have a multiple quantum well structure or another suitable structure for a laser diode. Such structures are described, for example, in S. Nakamura, G. Fasol, The Blue Laser Diode, Springer-Verlag Berlin Heidelberg 1997, page 223 et seq.

The semiconductor body may be formed on the basis of GaN, AlN, InN, AlGaN, InGaN, AlInN or AlGaInN. The term nitride compound semiconductor thus designates nitride compounds of elements of the third main group of the Periodic Table, such as GaN, AlN or InN, and the ternary and quaternary mixed crystals based on these compounds, such as AlGaN, InGaN, AlInN or AlGaInN.

The semiconductor body is preferably made on the basis of InₓAl_{y}Ga_{1-x-y}N, where 0≦x≦1, 0≦y≦1 and x+y≦1.

The present invention can be particularly advantageously used in particular in cases in which the p-conducting nitride compound semiconductor is doped with magnesium.

In accordance with a specific embodiment, the laser diode has a small resonator width of 20 μm or less, in particular of about 10 μm or less. In such configurations, the electrical connection is established via a large-area connection contact area that is electrically connected to the metallization of the resonatoro of the semiconductor chip, such metallization forming the resonator contact. The connection area itself and the connection to the resonator must be electrically isolated from the semiconductor since otherwise fault currents can arise.

The described configuration of the semiconductor laser diode enables at least a considerable part of the residual hydrogen contained in the semiconductor body to escape during operation of the laser diode so that a significantly increased contact resistance does not occur. The number of processes that can be used during production is enlarged as a result, since even hydrogen-critical processes no longer lead to a subsequent increase in the forward voltage during operation of the laser diode.

In addition to the above-listed advantages, the following advantages are afforded by the invention:

residual hydrogen which diffuses to the semiconductor surface during operation can escape from the semiconductor and thus does not bring about any contact impairment, and

a perforated contact that reduces the contact area can be dispensed with.

The invention is explained in more detail below using exemplary embodiments in connection with the drawings. Only the elements essential for understanding the invention are illustrated in each case.

### BRIEF DESCRIPTION OF THE DRAWINGS

FIG. 1 shows a diagrammatic sectional illustration of a detail from a semiconductor laser diode according to one embodiment of the invention (section along the line I-I of FIG. 2, but without the porions laterally of layer 22);

FIG. 2 shows a plan view of a laser diode with a contact structure in accordance with FIG. 1;

FIG. 3 shows a diagrammatic sectional illustration of a detail from a semiconductor laser diode according to another exemplary embodiment of the invention (section along the line III-III of FIG. 4, but without the porions laterally of layer 22); and

FIG. 4 shows a plan view of the laser diode with a contact structure in accordance with FIG. 3.

### DETAILED DESCRIPTION OF THE DRAWINGS

In the drawings, identical or identically acting constituent parts of the various exemplary embodiments are in each case provided with the same reference symbols.

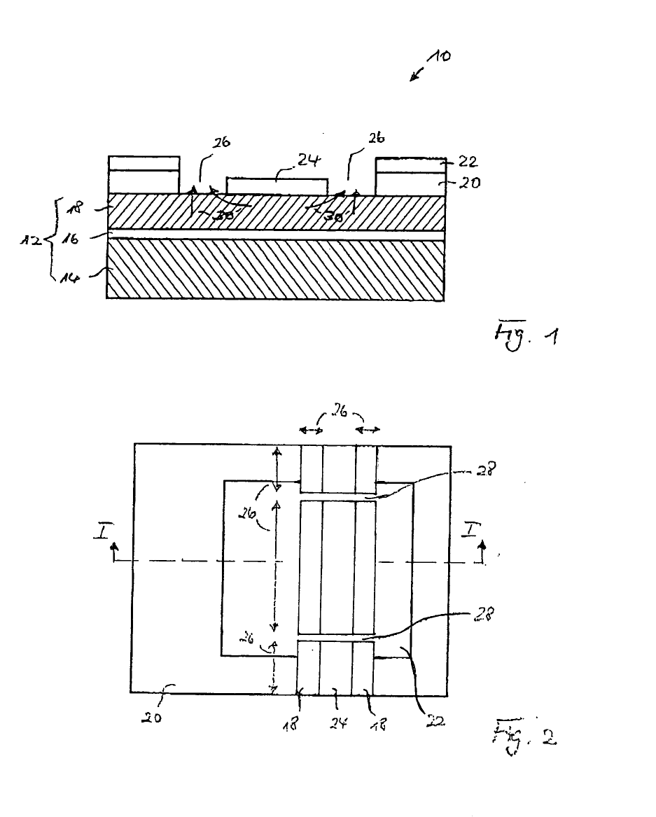

FIGS. 1 and 2 show a forward voltage (Uf)-stable (Al,In)GaN oxide strip laser 10. The oxide strip laser 10 has a semiconductor body 12, which is arranged on a substrate (which itself is not illustrated). Semiconductor body 12 contains an n-doped (Al,In)GaN layer 14, an active, photon-emitting structure 16 (active layer) and a p-doped (Al,In)GaN layer 18.

The n-type doping is effected for example with silicon, and the p-type doping with magnesium. The active layer may be formed by a quantum well or a multiple quantum well, for example a multiple quantum well structure based on InₓAl_{y}Ga_{1-x-y}N where 0≦x≦1, 0≦y≦1 and x+y≦1.

A resonator metallization 24 (resonator contact) in the form of an elongated, narrow contact strip is applied on the p-type semiconductor layer 18. A free region 26, in which no resonator metallization is applied on the semiconductor layer, is arranged on both sides of the resonator metallization 24 and, as can best be discerned in FIG. 2, extends along the axial extent of the resonator metallization 24 embodied in strip-like fashion.

Outside the free region 26, a large-area connection contact area 22 is arranged above a passivation layer 20, the said connection contact area serving for supplying current to the laser diode 10. The connection contact area 22 is electrically connected to the resonator metallization 24 by means of two connecting bridges 28, which lead from the connection contact area 22 to the resonator metallization 24. The bridges 28 are spaced from one another.

In the region of the connecting bridges 28, the passivation layer 20 with the overlying contact metal forms an electrically conductive connection to the resonator metallization 24. In this region the passivation layer 20 with the overlying contact metal is shaped like fingers that end adjacent to the resonator metallization 24. In the remaining regions, the free region 26 is covered neither by a passivation layer nor by any other protective layer. Consequently, residual hydrogen can diffuse from the interior of the p-type semiconductor 18 to the free region 26 and escape there from the semiconductor body 12, as indicated by the arrows 30 in FIG. 1. Consequently, a hydrogen-enriched boundary layer between the p-type semiconductor 18 and the p-type metallization 24 substantialy does not arise, which boundary layer, in conventional configurations, may lead to an impairment of the forward voltage Uf during operation of the laser diode.

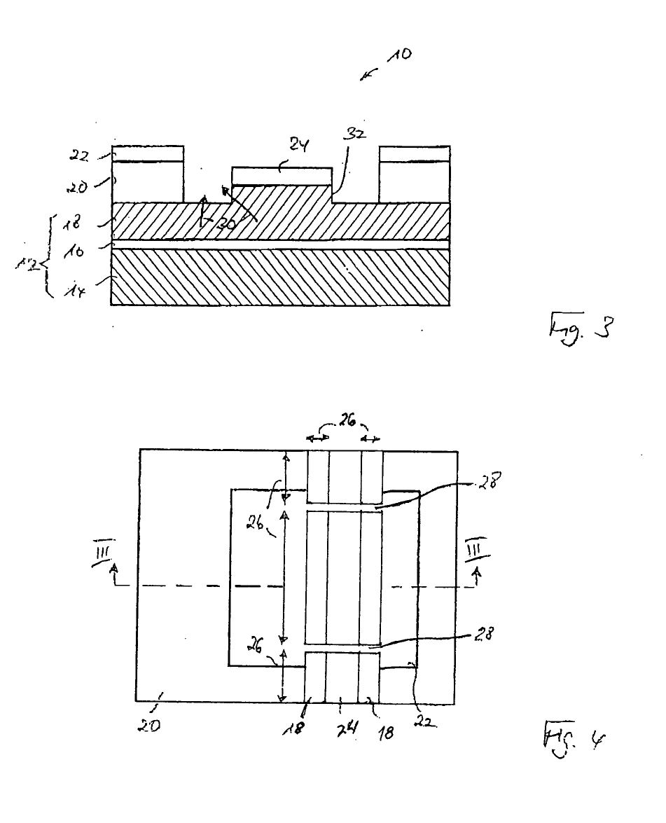

The ridge laser 10 of FIGS. 3 and 4, like the first embodiment described above, is likewise formed on the basis of (Al,In)GaN. In contrast to the oxide strip laser of FIGS. 1 and 2, a lateral waveguide structure 32 is embodied below the resonator metallization 24. The free region 26 directly adjoins the waveguide structure 32 and, as in the first exemplary embodiment, extends along the axial extent of the strip-like resonator metallization 24.

The configuration shown in FIGS. 3 and 4 affords two advantages. Firstly, as described above, residual hydrogen from the p-type semiconductor 18 can exit from the semiconductor body 12 in the free region 26 (arrows 30), and, secondly, the waveguide structure 32 directly adjoins the ambient air. Since the lateral wave-guiding is determined by the difference in the refractive indices of semiconductor material and the adjoining medium, that is to say air in the exemplary embodiment, an improved lateral wave-guiding results owing to the low refractive index of air compared with other conventional media (passivation materials).

The scope of protection of the invention is not limited to the examples given hereinabove. The invention is embodied in each novel characteristic and each combination of characteristics, which includes every combination of any features which are stated in the claims, even if this combination of features is not explicitly stated in the claims.

We claim:

1. A semiconductor laser diode comprising:
a semiconductor body (12) having a photon-emitting active layer (16) based on a nitride compound semiconductor,
a resonator contact (24) arranged on the semiconductor body (12),
a connection contact area (22) electrically connected to the resonator contact (24), and
an uncovered free region (26) located at the surface of the semiconductor body (12) and adjoining the resonator contact (24), at which free region hydrogen (30) can escape from the semiconductor body (12).

2. A semiconductor laser diode according to claim 1,
further comprising an insulating or high-resistance layer at the surface of the semiconductor body (12) in the free region (26).

3. A semiconductor laser diode according to claim 1,
wherein said resonator contact comprises a contact strip (24), and the free region (26) extends on both sides along said contact strip (24).

4. A semiconductor laser diode according to claim 3, wherein:
the connection contact area (22) is electrically connected to the resonator contact (24) at one or more contact zone(s) (28), and
the connection contact area (22) crosses the free region (26) toward the resonator contact at said contact zone(s).

5. A semiconductor laser diode according to claim 4,
wherein:
the connection contact area (22) and the contact zone(s) (28) are electrically insulated from the semiconductor body (12) by a passivation layer (20).

6. A semiconductor laser diode according to claim 1, wherein:
the free region (26) adjoining the resonator contact (24) forms a part of a lateral wave-guiding structure (32) of the laser diode.

7. A semiconductor laser diode according to claim 1, wherein:
the semiconductor body (12) comprises a layer sequence including an n-conducting nitride compound semiconductor (14), an active layer (16) and a p-conducting nitride compound semiconductor (18), and the resonator contact (24) is arranged on the p-conducting nitride compound semiconductor (18).

8. A semiconductor laser diode according to claim 7,
wherein:
the semiconductor body (12) is formed on the basis of GaN, AlN, InN, AlGaN, or InGaN.

9. A semiconductor laser diode according to claim 7,
wherein:
the semiconductor body (12) is formed on the basis of InₓAl_{y}Ga_{1-x-y}N where 0≦x≦1, 0≦y≦1 and x+y≦1.

10. A semiconductor laser diode according to claim 7,
wherein:
the p-conducting nitride compound semiconductor (18) is doped with Mg.

11. A semiconductor laser diode according to claim 1, wherein:
the laser diode has a resonator width of 20 μm or less.
